(19) United States
(12) Patent Application Publication
(10) Pub. No.: US 2025/0314687 A1
(43) Pub. Date: Oct. 9, 2025

(54) Conductor fault detection and localization

(71) Applicant: AURA Technologies, LLC, Chapel Hill, NC (US)

(72) Inventors: Dan Winkelstein, Raleigh, NC (US); Zachary Barkley, JR., Raleigh, NC (US); Alex Blate, Chapel Hill, NC (US); Douglas Bennett, Chapel Hill, NC (US); Anna Bennett, Chapel Hill, NC (US); Eric Strong, Orono, ME (US)

(21) Appl. No.: 19/170,288

(22) Filed: Apr. 4, 2025

Related U.S. Application Data
(60) Provisional application No. 63/574,410, filed on Apr. 4, 2024.

(51) Int. Cl. G01R 31/08; G01R 31/58

(52) U.S. Cl. CPC G01R 31/08; G01R 31/58

(57) ABSTRACT

A first instrument comprising at least one signal generator, at least one resistor, at least one voltage measurement device including a positive input and a negative input, at least one monitored conductor terminal coupled to a monitored conductor, at least one reference conductor terminal coupled to a reference conductor, and at least one processor operably connected to the at least one signal generator and the at least one voltage measurement device. An output of the at least one signal generator is electrically coupled to the at least one monitored conductor terminal via the at least one resistor, the positive input of the voltage measurement device is electrically coupled to the at least one resistor, the negative input of the voltage measurement device is electrically coupled to the at least one reference conductor terminal, and the at least one processor is configured to instruct the at least one signal generator to output a sinusoid waveform of at least a first frequency, read the at least one voltage measurement device, calculate the resonant frequency or the impedance of the circuit coupled to the at least one monitored conductor terminal and at least one reference conductor terminal, and calculate and output at least one of the resonant frequency or the impedance of the circuit at the resonant frequency.

### CROSS REFERENCE TO RELATED APPLICATIONS

The present application claims the benefit of and priority to co-pending U.S. provisional application No. 63/574,410, filed on Apr. 4, 2024, the content of which is hereby incorporated by reference as if set forth in its entirety herein.

### STATEMENT REGARDING FEDERALLY SPONSORED RESEARCH OR DEVELOPMENT

This/these invention(s) were made with Government support under contract N68335-21-C-0490 awarded by the United States Navy. The Government may have certain rights in the invention(s).”

### TECHNICAL FIELD

Embodiments described herein generally relate to detecting faults and, more particularly but not exclusively, to systems and methods for detecting and localizing conductor faults.

### BACKGROUND

A common failure mode or fault in electrical systems comprises short circuits or low-impedance paths between conductors or between a conductor and ground. Such faults may be due to, without limitation, failures of or damage to conductors, connection components, or semiconductor devices. Independent of cause, such faults may result in failure or loss of function in the associated system of the conductor, fires or heat damage, intermittent failures, and interference with or damage to other systems. Additionally, these failures may pose electrocution hazards to personnel.

Existing techniques for detecting such faults comprise the use of high-voltage (500 V to thousands of volts) “Megger” instruments, high resistance Ohmmeters, insulation testers, or similar instruments. These may or may not be effective for some faults and may not be acceptable in some applications because the high-voltage signals may damage the attached equipment. Additionally, these instruments are typically hand-held, stand-alone units, and conductors must be probed individually and by hand. Meggers and other instruments, such as insulation testers, can cause further damage to insulation due to arcing. This may be particularly dangerous in environments such as in combustible atmospheres, on flight lines, or where intrinsic safety requirements are applicable. Such instruments are also unable to non-destructively detect low, non-resistive impedances such as those associated with capacitive coupling. Increasing capacitive coupling—and attendant decreasing impedance—between conductors can indicate physical damage to or dielectric changes of insulators, or the likely evolution of an insulation fault. These conditions may not be severe enough to lead to arcing (and thus are invisible to a Megger).

A need exists, therefore, for improved systems and methods for detecting and localizing faults.

### SUMMARY

This summary is provided to introduce a selection of concepts in a simplified form that are further described below in the Detailed Description section. This summary is not intended to identify or exclude key features or essential features of the claimed subject matter, nor is it intended to be used as an aid in determining the scope of the claimed subject matter.

According to one aspect, embodiments relate to a first instrument. The first instrument includes at least one signal generator; at least one resistor; at least one voltage measurement device including a positive input and a negative input; at least one monitored conductor terminal coupled to a monitored conductor; at least one reference conductor terminal coupled to a reference conductor; and at least one processor operably connected to the at least one signal generator and the at least one voltage measurement device, wherein an output of the at least one signal generator is electrically coupled to the at least one monitored conductor terminal via the at least one resistor, the positive input of the voltage measurement device is electrically coupled to the at least one resistor, the negative input of the voltage measurement device is electrically coupled to the at least one reference conductor terminal; and the at least one processor is configured to instruct the at least one signal generator to output a sinusoid waveform of at least a first frequency, read the at least one voltage measurement device, calculate the resonant frequency or the impedance of the circuit coupled to the at least one monitored conductor terminal and at least one reference conductor terminal, and calculate and output at least one of the resonant frequency or the impedance of the circuit at the resonant frequency.

In some embodiments, the first instrument further includes prescribed set of two or more frequencies wherein, for each frequency F in the set, the at least one processor configures the at least one signal generator to output a sinusoid of frequency F, read the at least one voltage measurement device, and record the voltage at frequency F. In some embodiments, the at least one processor is further configured to calculate the at least one resonant frequency of the circuit coupled to the at least one monitored conductor terminal and the at least one reference conductor terminal from the set of measured voltages and calculate and output the impedance of the circuit at each frequency. In some embodiments, the at least one processor is further configured to input the set of frequencies and measured voltages into at least a first algorithm that determines and outputs at least one of whether a fault exists, the impedance of the fault, or the location of a fault. In some embodiments, the input to the at least first algorithm further comprise data about at least one of the topology, physical characteristics, or electrical characteristics of the electrical network coupled to the at least one monitored conductor. In some embodiments, the input to the at least first algorithm comprise at least a first set of frequencies and measured voltages recorded at a first time and a second set of frequencies and measured voltages recorded at a second time. In some embodiments, the first algorithm comprises a machine learning algorithm or artificial intelligence algorithm.

In some embodiments, the at least one processor is further configured to use the at least one voltage measurement device together with the at least one signal generator as a phase-sensitive detector or as a lock-in amplifier.

In some embodiments, the first instrument further includes a second voltage measurement device electrically coupled to the monitored conductor at a location different from that of the monitored conductor terminal.

In some embodiments, the instrument further comprises at least one network interface operably connected to at least one processor.

In some embodiments, the instrument is configured to communicate with at least one of a second instrument or another network node via at least one network. In some embodiments, the first instrument and second instrument are configured to coordinate via the at least one network to establish or maintain a phase relationship between the signal generator of the first instrument and the reading of the voltage measurement device of the second instrument. In some embodiments, the signal generator is coupled to the first monitored conductor and the first reference conductor, a voltage measurement device of the second instrument is electrically coupled to the first monitored conductor and the first reference conductor, and the first instrument and the second instrument are configured to coordinate via the at least one network. In some embodiments, the first instrument is configured to output a sinusoid of at least a first frequency and the second instrument is configured to read a voltage via a second voltage measurement device and record the voltage at the at least first frequency.

In some embodiments, the instrument is configured to transmit at least one frequency and measured voltage to another network node via at least one network. In some embodiments, the network node is configured to receive frequencies and measured voltages from the instrument, input the frequencies and measured voltage into at least a first algorithm that determines and outputs at least one of whether a fault exists or the location of a fault.

In some embodiments, at least one of the monitored conductor or the reference conductor is a conductor of a cable harness, wiring harness, network cable, coaxial cable, twinaxial cable, triaxial cable, power transmission line or network, circuit board, backplane, differential pair, grounding network, hull, chassis, or structure, undersea or underground cable, multiconductor cable, antenna or antenna system, semiconductor device, electric motor, or transformer. In some embodiments, the first algorithm is configured to use transfer learning.

In some embodiments, the instrument is configured such that the positive input of the first voltage measurement device is electrically coupled to a first terminal of the at least one resistor and a second terminal of the at least one resistor is electrically coupled to the monitored conductor, and a positive input of a second voltage measurement device is electrically coupled directly to the monitored conductor. In some embodiments, the instrument is configured to read a value from the first voltage measurement device and a value from the second voltage measurement device concurrently, and to calculate the current through the at least one resistor based on knowledge of the resistor.

### BRIEF DESCRIPTION OF DRAWINGS

Non-limiting and non-exhaustive embodiments of the invention are described with reference to the following figures, wherein like reference numerals refer to like parts throughout the various views unless otherwise specified.

FIG. 1 illustrates a system for performing fault detection and localization in accordance with embodiment;

FIG. 2 illustrates an instrument in operable connectivity with a circuit in accordance with one embodiment; and

FIG. 3 illustrates a workflow for performing fault detection and localization using the components of FIG. 2 in accordance with one embodiment.

### DETAILED DESCRIPTION

Various embodiments are described more fully below with reference to the accompanying drawings, which form a part hereof, and which show specific exemplary embodiments. However, the concepts of the present disclosure may be implemented in many different forms and should not be construed as limited to the embodiments set forth herein; rather, these embodiments are provided as part of a thorough and complete disclosure, to fully convey the scope of the concepts, techniques and implementations of the present disclosure to those skilled in the art. Embodiments may be practiced as methods, systems or devices. The following detailed description is, therefore, not to be taken in a limiting sense.

Reference in the specification to “one embodiment” or to “an embodiment” means that a particular feature, structure, or characteristic described in connection with the embodiments is included in at least one example implementation or technique in accordance with the present disclosure. The appearances of the phrase “in one embodiment” in various places in the specification are not necessarily all referring to the same embodiment. The appearances of the phrase “in some embodiments” in various places in the specification are not necessarily all referring to the same embodiments.

In addition, the language used in the specification has been principally selected for readability and instructional purposes and may not have been selected to delineate or circumscribe the disclosed subject matter. Accordingly, the present disclosure is intended to be illustrative, and not limiting, of the scope of the concepts discussed herein.

Electrical faults can cause economic losses, loss of service of infrastructure or transportation assets, and even loss of life. Automated early detection of evolving or present electrical faults and localization thereof can reduce or eliminate the impact of such faults and mitigate the aforementioned effects.

When a fault comprises a low-resistance path, but not a short circuit, the current drawn by the fault may be insufficient to activate circuit protection devices such as fuses or circuit breakers. Or, if the fault is not to ground, the fault may not activate ground fault or ground leakage protection devices. In some applications, electrical systems, sometimes described as resistively-grounded, are referenced to ground via a resistive path, such as by a 10 kΩ resistor. In these applications, some ground leakage may be expected during normal operating conditions or may be allowable, and this may further frustrate fault detection methods.

In some applications, such as those in which a fault only occurs at high voltages, is capacitive, or is in a resistively-referenced or resistively-grounded system, the fault not be detectable using a direct current (DC) measurement techniques or digital multimeter (DMM) techniques. This is because the fault appears in parallel with the aforementioned resistor or is not detectable at DC. DMM techniques may include those using an Ohmmeter or digital multimeter.

Detecting faults to ground may be accomplished using ground fault circuit interrupters (GFCIs), residual current detectors (RCD), or similar devices. Such devices are commonly used in mains electrical applications, particularly in wet areas such as bathrooms and kitchens and are often required by electrical codes. GFCIs detect conditions in which there is an imbalance between the current flowing through the phase and neutral conductors of an earth-referenced-neutral AC circuit. This imbalance indicates that some current is flowing to ground through a path other than the neutral conductor, such as a person's body. When the current imbalance exceeds a specified limit (typically on the order of tens of milliamps), a GFCI or RCD disconnects the circuit. Equivalent devices exist to protect multi-phase AC circuits, circuits or electrical systems that do not employ a neutral conductor, and may exist for certain DC applications.

GFCI, RCD, and similar devices are problematic in certain applications and cannot detect certain classes of faults. For example, large inductive loads, such as AC induction motors, are known to cause GFCIs to erroneously trip due to current lag at motor startup. GFCIs and similar devices cannot detect inter-phase or phase-to-neutral leakage and cannot detect evolving faults, such as insulation degradation, which may have high Ohmic resistance. For example, on a 120 VAC circuit, a GFCI with a threshold current of 30 mA will not detect ground faults of greater than about 4 kΩ.

GFCI, RCD, and similar devices may also be unusable in application configurations that are not ground-referenced or are ground-referenced through resistive coupling. In these cases, a certain amount of ground leakage is acceptable and/or expected. Such devices generally are not useful for CBM or prognostics because they do not activate or trip until a fault has occurred. Additionally, they generally do not provide data outputs to allow analysis of conductor behavior over time. Such devices may not be useful in applications where a system is required to continue operating even in the presence of a ground fault such as in certain industrial, defense, or maritime applications. Such devices generally do not expressly measure or report fault impedances nor do they generally provide fault localization information.

Localizing a fault comprises identifying the location of the fault along a conductor. For low-resistance Ohmic faults, techniques such as time-domain reflectometry (TDR) or cable thumpers are commonly employed. TDR-based techniques however are relatively ineffective for higher-impedance faults. Cable thumpers' disadvantages include their reliance on insulation breakdown and arcing in their principle of operation, that they are expressly manually-operated instruments, and rely on acoustic detection of the sound produced at a fault, which detection typically comprises a worker traversing the length of the conductor. As previously mentioned, high-voltage or high-energy signals may damage components of some systems-particularly low-voltage or digital systems-and thus cannot be used for fault localization in such systems. Or, they require that conductors be disconnected from sensitive components prior to testing. As previously mentioned, reliance on or the possibility of arcing may preclude the use of cable thumpers in certain environments such as in explosive atmospheres, flight lines, or where intrinsic safety requirements are applicable.

Although faults can be localized via the physical inspection of conductors, this typically requires human intervention and physical access to and visibility of the full extent of the conductors. In many applications, such as commercial shipping or aviation, conductors are embedded within a structure, run in conduits, or are otherwise inaccessible without disassembling the system or platform to gain access to segments of conductors. Such inspection may require specialized training, and faults may be occluded by other cabling, conduit, structures, or other components, frustrating visual inspection. Physical inspection, particularly of large or complex systems, is time-consuming and labor-intensive and typically incurs system downtime because systems are deenergized for workers' safety.

In some applications, it may be difficult, expensive, or time-consuming to access electrical cabling. For example, aircraft often have tens or hundreds of miles of copper cabling running throughout the aircraft, almost all of which is inaccessible without disassembling parts of the aircraft. Access to cabling in some naval or maritime applications may require cutting through bulkheads or decks or may otherwise be intractable while at sea. Early detection of evolving fault conditions, such as during routine or mandatory maintenance, can lead to proactive maintenance of conductors—including during planned maintenance periods—instead of unplanned maintenance or loss of safety- or mission-critical systems in the field. In defense applications, faster and more accurate fault identification and localization may reduce the time and labor associated with assessing and mitigating battle damage.

The disclosed embodiments concern the localization of low-impedance paths between a monitored conductor and a reference conductor. In the context of the present application, low-impedance means impedance (ohmic, reactive/complex, or both) under 100 kΩ. Impedance is measured between a monitored conductor, i.e., the conductor instrumented, and a reference conductor. In the present disclosure, when an instrument or instruments are taught to or described as having multiple couplings to a monitored conductor or reference conductor, such couplings may be at different locations along the conductor, whether or not such locations are described or specified. In the present disclosure, two points or locations are on the same conductor if, under normal operating conditions (e.g., in the absence of a fault), there is DC continuity between said points or locations. For example, a cable or bus bar in series with a low-resistance component, such as an inductive element or a closed switch, collectively comprise a single conductor. In the present disclosure, a metallic structure, such as the metal hull of a ship, may comprise a (single) conductor regardless of whether or not the structure is intended to be used to carry current under normal operating conditions or the use or reliance on the structure as a safety ground. In the present disclosure, the terms “ground”, “earth”, “earth ground”, “mains earth”, “mains earth ground”, and “safety ground” are synonymous unless stated otherwise. In the present disclosure, a reference conductor may or may not be coupled to ground and that in embodiments describing or implying the coupling of a reference conductor to ground, such coupling shall not be construed as limiting.

The embodiments herein provide novel techniques and systems for fault detection, localization, prognostics, diagnostics, and condition monitoring of electrical systems using resonance, impedance analysis, and ambient compensation techniques. These techniques are made with respect to, for example and without limitation, faults caused by low-impedance paths between these conductors, between a conductor and ground, or faults relating to the degradation or failure of semiconductor devices.

The disclosed embodiments measure the impedance of the monitored conductor at one or more frequencies and, in some embodiments, may also measure DC resistance. The impedance of a circuit is the sum of the resistances to current flow due to reactance (i.e., of capacitors and inductors) and non-reactive components, which are purely Ohmic resistances. Thus, a change in impedance between a monitored conductor and a reference conductor may be due to changes in one or more of Ohmic resistance, capacitive coupling, or inductive coupling between the conductors.

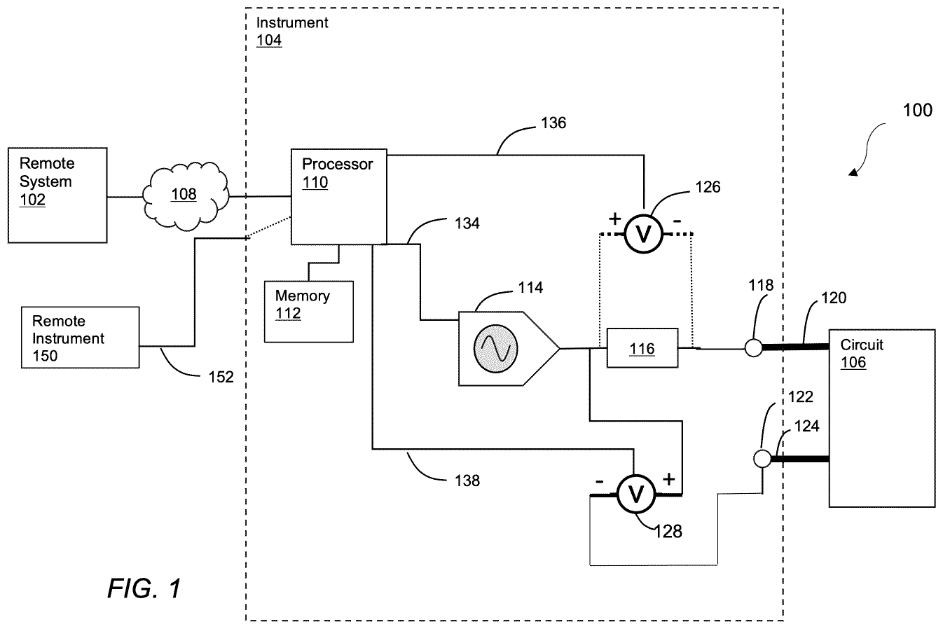

FIG. 1 illustrates a system 100 for performing fault detection and localization in accordance with embodiment. The system 100 may include a remote system 102 such as a control server, and an instrument 104 in communication with a circuit 106 over one or more networks 108. The instrument 104 may make measurements of the circuit 106 at two or more stimulus frequencies, possibly including DC (or, equivalently, 0 Hz). In some embodiments, the instrument 104 makes measurements of the circuit 106 over a specified or dynamically-selected range of stimulus frequencies. This range may comprise multiple orders of magnitude (e.g., 1 kHz to 10 MHz). In some embodiments, stimulus may comprise a sinusoid.

The instrument 104 may be configured to perform one or more self-calibration or self-test functions. In some embodiments, the instrument 104 may be configured such that a resistive load of a known value or a well-characterized reactive load can be coupled to a channel's inputs, possibly bypassing the channel's external connections. This may facilitate the calibration of voltage or current measurement devices or compensation for frequency-dependent variations in output amplitude. An instrument may be configured to perform an “open, short, load” or similar calibration and, in some embodiments, such calibration may be implemented in circuitry internal to the instrument such that calibration can be accomplished without user interaction. In some embodiments, a multi-port instrument may be configured to perform multi-port calibrations, such as open, thru, load or open, thru, short, load calibrations, to calibrate reference planes of multi-port measurements.

The instrument 104 may be configured such that a known resistive or reactive load can be coupled between the monitored conductor and reference conductor ports of a channel, i.e., while still coupled to the monitored circuit 106. This capability may be used for testing, validation, calibration, circuit characterization, or other functions of or performed by the one or more channels of instruments that may be coupled to the monitored conductor. In some embodiments, this capability may be used to tune, train, retrain, test, or verify fault localization models or algorithms.

The instrument 104 may make measurements of the circuit 106 at two or more stimulus frequencies, possibly including DC (or, equivalently, 0 Hz). In some embodiments, the instrument 104 makes measurements of the circuit 106 over a specified or dynamically-selected range of stimulus frequencies, the range of which may comprise multiple orders of magnitude (e.g., 1 kHz to 10 MHZ).

In some embodiments, the frequency range is sampled at discrete points which may be chosen according to a formula, heuristic, algorithm, or configuration and, in some embodiments, the discrete points are chosen on a logarithmic scale (e.g., N points per decade). In some embodiments, the instrument may make measurements over a continuous range or sweep of frequencies. In some embodiments, the frequency range may be selected or adjusted dynamically according to, without limitation, past or present measurements, user input, configuration, data pertaining to the location of one or more channels' coupling(s) to circuit 106, or input received via network 108. In some embodiments, a signal generator may be configured to output stimulus of the form of an impulse, pulse train, chirp, or step function and the instrument 104 may make measurements of the circuit's response to such stimuli.

The circuit 106 may refer to one or more electrical systems. Additionally, each port of one or more instruments may be connected to a different circuit.

The network(s) 108 may link the various components with various types of network connections. The network(s) 108 may be comprised of, or may interface to, any one or more of the Internet, an intranet, a Personal Area Network (PAN), a Local Area Network (LAN), a Wide Area Network (WAN), a Metropolitan Area Network (MAN), a storage area network (SAN), a frame relay connection, an Advanced Intelligent Network (AIN) connection, a synchronous optical network (SONET) connection, a digital T1, T3, E1, or E3 line, a Digital Data Service (DDS) connection, a Digital Subscriber Line (DSL) connection, an Ethernet connection, an Integrated Services Digital Network (ISDN) line, a dial-up port such as a V.90, a V.34, or a V.34 bis analog modem connection, a cable modem, an Asynchronous Transfer Mode (ATM) connection, a Fiber Distributed Data Interface (FDDI) connection, a Copper Distributed Data Interface (CDDI) connection, an optical/DWDM network, a serial network, such as RS-485 or Controller Area Network (CAN), or other digital bus or other wired or fiber-optic network recognizable to one of ordinary skill in the art that may presently exist or in the future be invented.

The network or networks 108 may also comprise, include, or interface to any one or more of a Wireless Application Protocol (WAP) link, a Wi-Fi link, a microwave link, a General Packet Radio Service (GPRS) link, a Global System for Mobile Communication G(SM) link, a Code Division Multiple Access (CDMA) link, or a Time Division Multiple access (TDMA) link such as a cellular phone channel, a Global Positioning System (GPS) link, a cellular digital packet data (CDPD) link, a Research in Motion, Limited (RIM) duplex paging type device, a Bluetooth radio link, satellite network or link, free-space optical network or link, a wireless broadband communication standard such as Long Term Evolution (LTE), 3G, 4G, 5G, 6G, or other present or future variants or versions thereof, or an IEEE 802.11-based link or other wireless, radio frequency, or electromagnetic network that may presently exist or in the future be invented.

One or more processors 110 executing instructions stored on memory 112 may control functioning of one or more components to gather data regarding the circuit 106 and possible faults therein. The processor(s) 110 may comprise a microprocessor, microcontroller, field-programmable gate array (FPGA) or other programmable logic device, digital signal processor (DSP), system-on-chip, some combination thereof, or other processing or computing element(s) known to one of ordinary skill in the art. The processor(s) 110 may execute one or more machine learning models or other algorithms for analyzing data received from the circuit 106 to identify, characterize, or localize faults.

The memory 112 may be L1, L2, L3 cache, or RAM memory configurations. The memory 112 may include non-volatile memory such as flash memory, EPROM, EEPROM, ROM, PROM, or volatile memory such as static or dynamic RAM, as discussed above. The exact configuration/type of memory 112 may of course vary as long as instructions for performing fault detection, characterization, and localization can be performed by the system 100.

The signal generator 114 may generate one or more stimuli used for detecting a fault somewhere in the circuit 106. The signal generator 114 may comprise one or more of a digital-to-analog converter (DAC), a fixed or adjustable oscillator, a voltage-controlled oscillator, phase-locked loop, temperature-compensated, GPS-disciplined oscillator, synthesizer, vector signal generator, direct digital synthesis circuit, or other type signal generation devices whether available now or invented hereafter. In some embodiments, the output of the signal generator 114 may be buffered or amplified by a discrete amplifier circuit or an operational amplifier.

The output of the signal generator 114 may be galvanically connected through a matching or sense resistor 116 to a monitored conductor terminal 118 connected to a monitored conductor 120. In some embodiments, the signal generator's 114 zero-volt or inverting output may be galvanically connected to a reference conductor terminal 122 connected to a reference conductor 124. The signal generator's 114 output may be AC-coupled to the monitored conductor 120. The signal generator's 114 output may be coupled to a monitored conductor terminal 118 or to a monitored conductor 120 through one or more passive radio frequency (RF) components, such as a directional coupler, attenuator, or circulator or active variants thereof. The signal generator's output may be coupled through a variable-gain amplifier or variable attenuator.

The stimulus frequencies or ranges of stimulus frequencies may be selected based on known characteristics of the circuit 106. In some embodiments, the known characteristics of the circuit 106 may enable the analysis of a specific segment of the circuit 106. For example, the monitored conductor 120 may comprise a large inductive element such as a motor winding, the reactance of which increases with frequency. A relatively high stimulus frequency will therefore be blocked by the inductive element, resulting in a measurement of only the intervening segment. This may help improve fault localization.

Voltage and/or current measurement devices 126 and 128 may be connected to at least one point along the signal generator's 114 output signal path or return signal path. In some embodiments, such connections may be located at points on the monitored conductor 120. Voltage may be measured before and after a matching or sense resistor 116, and current may be calculated using Ohm's law given the known value of said resistor 116. In some embodiments, the phases of the measured voltage, current, or output signal may also be measured. Each voltage and/or current measurement device 126 or 128 m ay comprise an analog-to-digital converter (ADC). In some embodiments, voltage and/or measurement devices 126 or 128 may be connected to processor 110 via a digital connection 136 or 138, respectively. In some embodiments, signal generator 114 may be connected to processor 110 via a digital connection 134. In some embodiments, a digital connection 134, 136, or 138 may comprise distinct or shared lines for one or more of clock, data out, data in, sample, chip select, read, write, or other digital signals. In some embodiments, processor 110 may be galvanically-isolated from a voltage and/or current measurement device 126 or 128 or a signal generator 114. In some embodiments, a voltage measurement device 126 or 128 or a signal generator 114 may comprise or be implemented, at least in part, by processor 110, e.g., such as in the case of a microcontroller with built-in ADCs, DACs, or related functions. In some embodiments, an ADC and a DAC may share the same clock, reference clock, or clock phase reference.

The generation or synthesis of sinusoidal or periodic stimulus signals from the signal generator 114 may be implemented, at least in part, using a look-up table, possibly in conjunction with a phase accumulator. Some embodiments may be configured to generate or synthesize stimulus signals having configurable or arbitrary waveforms, which may be non-sinusoidal, such as a square wave, impulse, step function, noise, or arbitrary periodic function

In some embodiments, the processor 110 may configure a DAC to produce a given waveform at a given frequency. In some embodiments, the processor 110 is configured to configure an ADC to sample at a given frequency or sample rate.

In some embodiments, an ADC is configured to sample at the same frequency or in- phase with a stimulus signal from the signal generator 114. In some embodiments, an instrument's noise rejection may be improved by at least 10 dBc by configuring an ADC's sample clock such that an ADC samples at the same frequency as a stimulus signal and in-phase or at a known phase angle with respect to the stimulus signal. This architecture may be similar to a discrete-time equivalent of a lock-in amplifier, sometimes known as a phase-sensitive detector, phase-sensitive detection, or direct down-conversion.

The monitored conductor 120 may be an insulated conductor, such as an insulated electrical or data wire, insulated electrical cable, or a conductor of a coaxial, triaxial, or twin-axial cable. In some embodiments, the reference conductor 124 may be an insulated conductor such as, without limitation, insulated electrical or data wire, insulated electrical cable, or a conductor of a coaxial, triaxial, or twin-axial cable. In some embodiments, the reference conductor 124 may be any conductive medium, including a medium not intended for use as a conductor in general or within the relevant part of the system in question, such as, without limitation, water or damp earth or sand, grounding or earthing rods, metal or conductive structural components, conduits or cable trays, cable races, metalwork, other electrical components, a conductive chassis, etc. For example, the reference conductor 124 may refer to a structural component such as, without limitation, a ship's (metallic) hull, a chassis, frame, fuselage, beam, vehicle component, conduit, cable tray, etc. In some systems, the neutral leg of a single-or multi-phase AC system may be referenced to ground via a resistor while phases are otherwise galvanically-isolated. The instrument 104 may be configured to ignore the impedance of the ground-reference resistor when attempting to detect faults from neutral or phases to ground.

In some embodiments, the reference conductor 124 may be referenced to a ground or a “zero-volt” potential of instrument 104 or to the ground/earth of circuit 106 or its containing system. The reference conductor 124 may be, without limitation, a current-carrying conductor such a phase of a multi-phase AC system; a neutral conductor; a data or communications line, etc.

A channel to the circuit 106 may be operably connected to or appear in series or parallel with certain circuit components. These components may include, without limitation, switches, switching components, block switches, motors, induction motors, linear induction motor, inputs, outputs, or neutral terminals of power converters or inverters (AC-DC, DC-DC, DC-AC, AC-AC), capacitors or capacitor banks, rectifiers, thyristors, SCRs, transistors, relays, bus bars or bus rails, terminals, connectors, or receptacles, signal inputs or outputs, circuit breakers, or circuit protection devices.

The instrument 104 may analyze the impedance of these components to determine one or more of a variety of characteristics indicative of a fault. The instrument 104 may model or analyze expected DC or complex impedance, or resonance characteristics to determine the type(s) of fault. In some embodiments, instrument 104 may be configured with or may receive input comprising information about these components or circuit 106, such as a representation of at least a portion of the schematic or physical topology of circuit 106 or characteristics of one or more of these components.

In some embodiments, one or more aspects of a fault identification, classification, or localization algorithm or model may incorporate data about the physical topology and configuration of the circuit under test, such as connectivity, lengths of conductors, conductor properties, the identities of electrical components, schematics, mechanical drawings or equivalent, etc. Such data may comprise inputs to the instrument 104, another system, such as remote system 102, algorithms, or models; previous measurements or calculations; or stored configurations. The instrument 104 may be configured to consider the physical topology of the circuit under test when, for example, choosing or recommending to the user which points in the circuit to probe, selecting frequency ranges, or selecting algorithms or models.

Localization calculations are generally inexact, i.e., there is likely some uncertainty in the physical location of a fault. A localization algorithm may be configured, in some embodiments, to output the predicted region in which the fault likely is located, possibly incorporating information pertaining to the probability of the fault being at certain locations within the region. In some embodiments, such probability information may be displayed to a user in the form of a heat map or other color-coding scheme, possibly overlayed on a diagram, map, plan view, or equivalent of the circuit under test or its containing system or structure.

In some embodiments, a localization algorithm or a post-processing step or function may calculate one or more physical locations proximate to the fault where the respective conductors are accessible to a user (e.g., access panels, crawl spaces, etc.) or may compute a route to guide a user to the fault location. In some embodiments, fault location, access, routing, or related information may comprise or be accompanied by information relating to safety protocols or procedures, hazards, identification of lock-outs, other users or activities proximate to a fault or a route to a fault, systems coupled to a conductor, inspection or repair instructions, or other related information or instructions.

In some embodiments, this modelling or analysis may be used to reduce the number of connection points required to detect requisite fault conditions by excluding redundant connection points and/or connection points where probative signals or measurements are unlikely or impossible. For example, and as previously mentioned, an inductive component will effectively block higher frequencies, making downstream conductors and components essentially invisible. This modeling may also be used to select or optimize frequency ranges of interest for monitoring each circuit or to select the appropriate signal generator(s) and/or voltage/current measurement device(s) for the requisite frequency range(s). Knowledge of model outputs or measurements of a circuit's impedance may be used to configure the stimulus' amplitude, for example, to make better use a voltage/current measurement device's dynamic range.

The instrument 104 may further comprise an oven-controlled oscillator; rubidium oscillator, or other high-precision or “atomic” clock source; a GPS-disciplined oscillator or other high-precision and/or low-phase-noise frequency reference. In embodiments in which a stimulus is produced by a first instrument and measurements are made on a second instrument, the monitored conductor 120 may be used to establish phase alignment or phase-lock between the first instrument and the second instrument for the purposes of the measurement. Such embodiments may use this technique to avoid the necessity for inter-instrument synchronization connections. Some embodiments may comprise an inter-instrument synchronization connection 152, providing clock synchronization, phase-lock, or phase alignment between instrument 104 and remote instrument 150. In some embodiments, inter-instrument synchronization connections 152 may comprise point-to-point connections between instruments, a bus or ring shared by multiple instruments, or radio frequency (RF)/wireless signaling. Wired inter-instrument synchronization connections 152 may comprise wiring or cables including, without limitation, coaxial, triaxial, or twin-axial flexible, semi-flexible, or rigid cables, differential or twisted pair cables, or fiber optic lines. In some embodiments, wired or optical inter-instrument synchronization connection 152 may be configured as a cable of one or more known standard lengths to assist in speed-of-light compensation or may use phase-stable cables.

The location of a fault in a circuit 106, such as a low-resistance Ohmic path between a monitored conductor 120 and a reference conductor 124, affects the complex impedance of the circuit 106. In other words, a change in location of a fault will result in a change in the complex impedance of the circuit 106. A change in the complex impedance of the circuit 106 may alter a resonant frequency of circuit 106, the magnitude of such resonance, or phase components thereof. The analysis of complex impedance, which is a function of voltage and current, may comprise analysis of voltage and current measurements/waveforms individually or severally including, without limitation, comparison of the phase and/or magnitude of the voltage and current waveforms at one or more frequencies.

In the present context, determining the complex impedance of the circuit 106 comprises measuring complex voltage and current over a range of frequencies. Each complex voltage or current measurement comprises a vector representing the magnitude and phase of the voltage or current. Accordingly, the distance between the stimulus source (or otherwise the point of measurement) and the fault should impact the phase of observed reflections (or attenuations) caused by the fault. These differences may be very small, may be obfuscated by other complexities of the circuit 106, or may otherwise be non-obvious to an analyst using conventional DSP and algorithmic techniques.

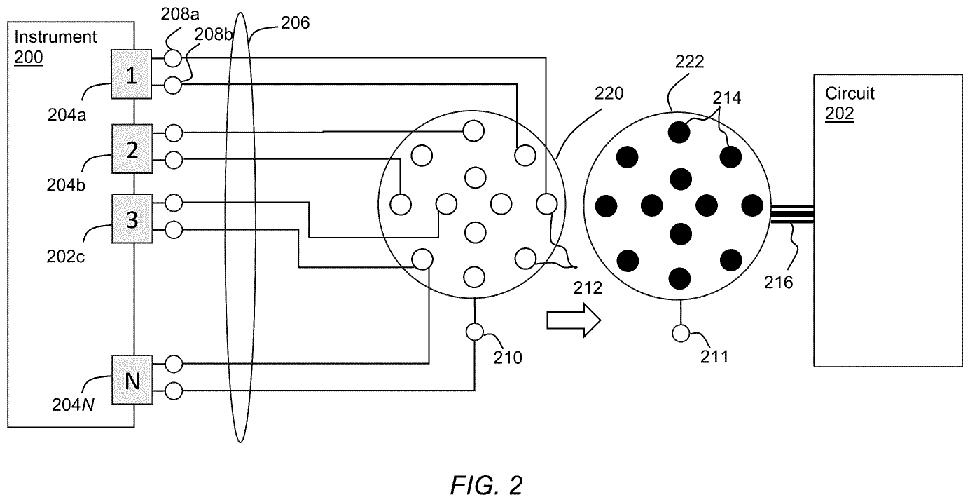

FIG. 2 illustrates an instrument 200 such as the instrument 104 of FIG. 1 in accordance with one embodiment. The instrument 200 may comprise multiple channels which may be operated individually or severally in series or in parallel. In some embodiments, at least one channel is capable of output stimulus signals and, in some embodiments, one or more channels may be capable of only measuring voltage/current.

In some embodiments, instruments 200 or their associated processors (not shown in FIG. 2) may be organized in a distributed fashion and may be interconnected by a data network. Instruments 200 or their associated processors (not shown in FIG. 2) may be interconnected by inter-instrument synchronization connections 152. In some embodiments, the instrument 200 may be configured to make independent measurements of multiple circuits concurrently, for example, using multiple signal generators and voltage/current measurement devices.

The channels of one or more instruments 200 may be coupled to a circuit in a “multi-port” configuration using ports 204a, 204b, 204c, . . . , 204N, where N is the number of ports. Each port 204a, 204b, 204c, . . . , 204N may be configured with channels configured with or for a cable 206. Each port 204a, 204b, 204c, . . . , 204N may be associated with a monitored conductor and a reference conductor. For example, port 204a may be associated with monitored conductor 208a and reference conductor 208b.

The multi-port configuration of one or more instruments 200 may comprise or be used as a multi-port network analyzer or multi-port vector network analyzer. In some embodiments where multiple instruments are used in a multi-port configuration, the instruments may share a common reference clock or phase reference and some such embodiments may comprise or be used as a distributed network analyzer or distributed vector network analyzer. Unless otherwise stated, measurements involving one channel or port shall be understood as being applicable to multi-port configurations.

The cable may terminate in connector pins 212 of a connection plug 220. The cable 206 may also include a connection shield 210 to protect the cable from outside interference and ensure signal integrity. In some embodiments, connection shield 210 is connected or otherwise referenced to ground. The connector pins 212 may interface with receptacles 214 of a receiving connector 222, which is connected by cable 216 to the circuit 202. In some embodiments, connection shield 210 couples to the connection plug 220 which, when connected to receiving connector 222, couples to connection shield 211 which may, in some embodiments, be connected to a conductor of cable 216 which conductor may serve as a shield. This paragraph describes connection plug 220 in the manner of a “male” connector and receiving connector 222 in the manner of a “female” connector. However, the teachings of this paragraph do not depend on the “gender” of the connectors or the assignment of pins or receptacles to the respective connectors, and such teachings are equally applicable to hermaphroditic connectors, RF connectors, and connectors having both pins and receptacles in each of the connection plug 220 and receiving connector 222.

The instrument 200 may apply a first stimulus to a first monitored conductor 208a and a second stimulus to a second monitored conductor 208b. The first stimulus and second stimulus may be at the same frequency with a constant phase offset. For example, the second stimulus is 180° out-of-phase with respect to the first stimulus. When the constant phase offset is 180°, this configuration is denoted “differential stimulus” and the first conductor 208a and second conductor 208b are jointly denoted as a differential pair.

In some embodiments, differential stimulus may be effectuated by a signal generator with a differential output, by coupling a signal generator to a single-ended-to-differential amplifier or driver, or as a pseudo-differential signal created by two signal generators. To the extent that neither conductor 208a and 208b of a differential pair is a reference conductor (i.e.., treated as a zero-volt or ground reference) and because the pair is driven by a differential signal, measurements are typically of the complex differential impedance of the differential pair. This enables the detection of certain types of faults specific to differential transmission lines.

A channel's coupling to a conductor may comprise a mechanical switch or relay (not shown in FIG. 1 or 2) that, when configured to be open, isolates the channel from the conductor. Some embodiments are configured with high-voltage-rated or high-isolation-rated mechanical switches or relays. For example, such a switch or relay may be installed in series with the coupling between resistor 116 and monitored terminal 118 and, in some embodiments, a second pole of said switch or relay or a second relay may be installed in series with the coupling between the negative terminal of voltage/current measurement device 128 and reference terminal 122. In some embodiments, a channel or another part of an instrument 200 may sense the voltage of a conductor and, in such embodiments, the instrument may be configured to disconnect or isolate the respective channel(s) from said conductor if the voltage exceeds a prescribed threshold. In some embodiments, the detection and control circuitry that controls an isolation switch or relay may be configured or designed to operate autonomously with respect to processor 110 including, in some embodiments, effectuating such control in conditions where processor 110 is booting, has crashed, is busy, etc. In some embodiments, an instrument may be configured such that measurements are made only when monitored conductors are deenergized. In these configurations, channels are isolated when the monitored conductors are energized and may, in some embodiments, reman isolated until measurement or stimulus functions may be required.

The instrument 200 comprise one or more network or digital communications interfaces, such as, without limitation, Ethernet, Wi-Fi, Modbus, or RS-485 or other such interface(s) as may be required to interface with network 108. The instrument 200 may be configured to communicate with another system such as the remote system 102 of FIG. 1. The remote system 102 may be a server or other computer (“control server”). In some embodiments, multiple instruments may be configured to communicate with a particular control server. The instrument 200 may convey raw or processed data or results to a control server. A control server may convey commands, configuration, software or firmware, models or model parameters, or other data to an instrument. In some embodiments, a control server may coordinate the behavior of multiple instruments, including, but not limited to, the coordination or configuration of multi-port configurations. In some embodiments, communications with a control server or other system may be authenticated, encrypted, or both. In some embodiments, data or results may be digitally-signed and/or encrypted.

In some embodiments, an instrument 200, a control server, or another remote system such as the remote system 102 of FIG. 1 may be configured to transmit a message to another system, alert a user, trigger an alarm or other annunciator, display information or symbology on a user interface, or otherwise act upon the detection and/or localization of a fault, or the determination that a previously-detected fault has been resolved or cleared. Some embodiments may be configurable such that this type of alarm function may be suppressed or ignored for a particular conductor, group of conductors, or location(s). This may be useful in situations or at times such as during repair or maintenance of the same; when performing training, tuning, or transfer learning on an algorithm; or during calibration or system testing. This suppression may be effectuated automatically, such as if an instrument is performing testing or calibrating itself or of or in coordination with another instrument.

The instrument 200 may be configured to receive data or commands from or transmit data or commands to another instrument or another system such as a control server. In some embodiments, an instrument such as the instrument 200 may be configured to function as a control server. In some embodiments, an instrument or control server may be configured to inform another system when a fault or other condition is detected.

A control server may be configured to receive information from another system about the state of a monitored conductor, such as whether it is energized or deenergized, and may communicate with an instrument 200 the same. The control server may store or archive data collected by an instrument. The control server or may process this data for purposes such as, without limitation, identifying faults, characterizing faults, localizing faults, training or assessing machine learning models, effectuating transfer learning, or detecting model drift.

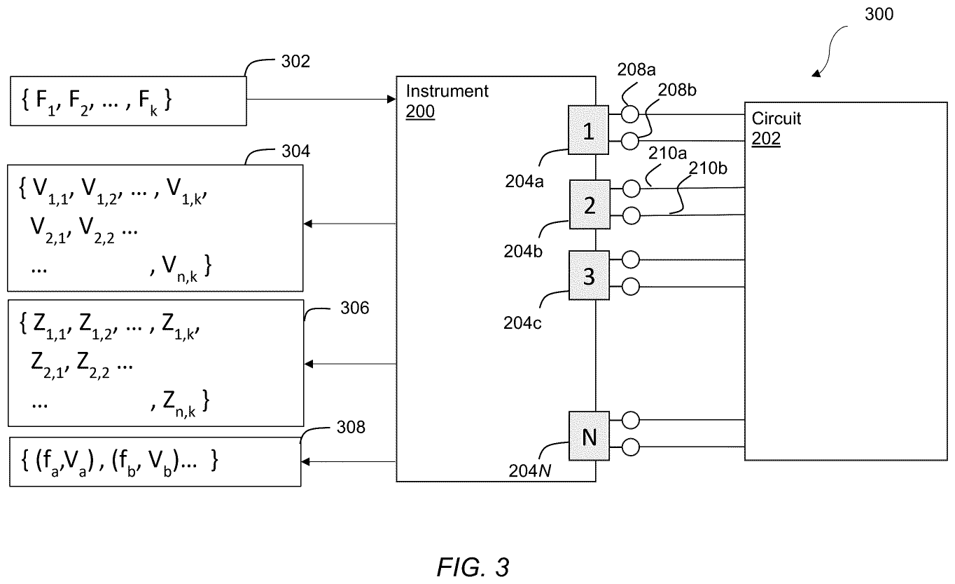

FIG. 3 illustrates a workflow 300 for performing fault detection and localization using the components of FIG. 2 in accordance with one embodiment. First, a plurality of input stimulus frequencies F₁, F₂, . . . , Fₖ 302 are provided to or are otherwise generated by the instrument 200. For example, the instrument 200 may make measurements of the circuit 106 or 202 over a range of stimulus frequencies 302, such as those over multiple orders of magnitude (e.g., 1 kHz to 10 MHz). The signal generator of FIG. 1 may provide these stimulus frequencies 302 in the form of a sinusoid, impulse, pulse train, chirp, step function, or other prescribed waveform(s) and the instrument 200 may make measurements of the circuit's response to such stimuli.

The circuit 202 may provide a response for each of the inputted frequencies 302. Specifically, the instrument 200 may measure the voltages and currents between monitored conductors and reference conductors at specific frequencies. Digital signal processing techniques can be used to extract the amplitude and phase of a signal at a specific frequency, even if the signal is considerably below the noise floor. This design relies on injecting the signal at the previously-determined resonance frequency into the conductors under test and measuring that signal at other strategic locations. Lock-in amplifiers may be used to detect and measure very small AC signals, such as a few nanovolts. Accurate measurements may be made even when the small signal is obscured by noise sources many thousands of times larger. As previously discussed, lock-in amplifiers use a technique known as phase-sensitive detection to single out the component of the signal at a specific reference frequency and phase. Noise signals, at frequencies other than the reference frequency, are rejected and do not affect the measurement.

In some embodiments, the instrument 200 further comprises channels configured to measure the voltages 304 and currents (not shown in FIG. 3) through one or more conductors. The non-normative notation of the voltages 304 is that Vᵢⱼ denotes the voltage at port i with stimulus at frequency j. Voltages 304 and currents (not shown in FIG. 3) may be scalar or complex. In some embodiments, current is measured using a current transformer, Hall-effect sensor, semiconductor or integrated circuit current probe, other current measurement device, or, as previously described, by measuring the voltage drop across a resistor of a known value, such as sense resistor 116. In some embodiments, current and voltage may be sampled at or above the Nyquist sample rates for frequencies high enough to detect certain types of faults in connected devices. For example, in the case of failing bearings, the frequency content of interest typically falls within ten to twenty harmonics of the line frequency (e.g., under 2 kHz, for which the Nyquist sample rate is 4 kHz). To the extent that mains line voltages range from 120 V to 480 V, device currents may be many tens or even hundreds of Amperes, and the high-frequency content of interest is typically on the order of less than 100 mV or 100 mA.

The high-dynamic-range/high-signal-to-noise-ratio methods taught in the present disclosure may be in the data acquisition components of embodiments of the aforementioned prognostic/diagnostic capabilities. In like manner, the analytical and algorithmic time-domain, frequency-domain, and DSP techniques and supporting hardware of the disclosed instrument may, be extended or transferred to service the aforementioned prognostic/diagnostic capabilities.

The complex impedance values 306 are analyzed to identify, inter alia, one or more resonant frequencies 308. The non-normative notation of the complex impedance values 306 is that Zᵢⱼ denotes the complex impedance measured at port i with stimulus frequency j. The non-normative notation of the resonant frequencies 308 is that (fᵢ, Vᵢ) denotes the i^{th} resonant frequency, fᵢ, and the signal magnitude at said frequency, Vᵢ, for example, the maximum or minimum magnitude observed at fᵢ. While signal magnitude may be in units of Volts, the aforementioned notation's use of the letter “V” is illustrative and the magnitude may be in other units, may be non-scalar, or may be a data structure. In some embodiments, a resonant frequency may be characterized as a local or global minimum of the scattering or S₁₁ parameter, voltage standing wave ratio (VSWR), or return loss. Some embodiments may measure or compute one or more S-parameters of a circuit 202, i.e., one or more of S₁₁, S₁₂, S₂₁, and S₂₂, reported at frequencies of interest. In some embodiments, a resonant frequency may be characterized by a local or global extreme of current, voltage, power, or complex impedance.

In transmission line analysis, a resonant frequency may be a frequency where the inductive and capacitive impedances of the circuit are of equal magnitude and, because they are 180° out of phase, they add to zero. At such resonant frequency, any remaining impedance is purely Ohmic. Some embodiments may use this characteristic of resonance to measure resistance between a monitored conductor 208a and a reference conductor 208b. In some embodiments, the aforementioned resonance calculation method may be used to distinguish faults from expected or design-intrinsic resistance or impedance.

Analyzing complex impedance may help identify changes in capacitive coupling between conductors. These changes may indicate, for example and without limitation, a breakdown of or damage to insulation or of semiconductor or switching components. In some embodiments, analyzing complex impedance may be used to identify faults or evolving faults in connectors, contacts, or junctions in a circuit. Similarly analyzing the complex impedance may help detect and localize loss-of-continuity to parts of a conductor, such as due to severing of a cable.

The complex impedance measurements of a circuit may be made periodically or sporadically over time and may be stored or archived. In some embodiments, changes in a circuit's complex impedance over time may be processed by algorithms executed by the processor 110 of FIG. 1 and, in some embodiments, such algorithms may characterize certain changes as benign or indicative of a present or evolving fault. Algorithms may process changes over time in multi-port complex impedance measurements of a circuit and, in some embodiments, such processing may more accurately characterize and determine causes or contributing factors of changes in complex impedance.

The embodiments herein may implement one or more machine learning (ML) models, possibly in conjunction with DSP or other algorithms to infer or predict fault locations. Referring back to FIG. 3, the instrument 200 may measure the voltage 304 and complex impedance values 306 of the circuit 202 over the range of input frequencies 302. As discussed previously, the stimulus may be applied in one or more locations on the circuit 202 and measurements may be made at one or more locations on the circuit 202.

The instrument 200 may apply one or more feature extraction algorithms with respect to the impedance values 306. The features may be inputted into one or more models executed by the processor 110 of FIG. 1 or a remote system 102. These models may include ML model(s), the outputs of which include data relating to the location of a fault in the circuit 202. The feature extraction algorithms may employ DSP methods, time-series methods, feature engineering methods, heuristics, or the like.

The machine learning models may include supervised or unsupervised learning models. Supervised models may be trained on labelled or unlabeled data, and such training data may comprise simulated data, empirical measurements, or a combination thereof. The feature extraction algorithm(s) or ML model(s) used for fault localization on a particular monitored conductor may be selected based on known or inferred characteristics of said conductor. In some embodiments, such characteristics may further comprise measurements of the monitored conductor, schematics or netlists, or information about the topology of the conductor.

An ML model trained in one environment may not perform well if used in another environment. Transfer learning, in simple terms, is a process in which a pre-trained ML model is tuned or partially retrained in a new environment. This process is typically far more efficient and may result in a more accurate model compared to training a model from scratch in the new environment. Transfer learning is also helpful in instances where training data of the new environment may not be available.

Some embodiments may employ transfer learning, inter alia, to adapt an ML model trained on a particular type of circuit to a specific circuit or variant thereof. The transfer learning process, including tuning or additional training, may be automatic or automated. The calculation of fault identification, characterization, or localization may be implemented in the instrument and, in some embodiments, may be at least partially implemented in the hardware of the instrument, which hardware may comprise programmable logic, such as an FPGA.

Calibration, training, or the effectuation of transfer learning of instruments for use in new or previously unknown circuits may be aided or facilitated by a capability to insert faults (low-resistance paths between a monitored conductor and a reference conductor) of known Ohmic values and/or at known locations in the circuit. In some embodiments, one or more of an instrument's ports may be configured such that it can switch/couple one or more known resistances across the port's terminals, i.e., to induce a known, simulated fault.

In some embodiments, multiple models may provide a determination of a fault location. The processor 110 or remote system 102 may provide a single location estimate based on the output from the one or more models, along with a confidence score or uncertainty metric associated with the outputted location estimate.

A lock-in amplifier can extract the amplitude and phase of a single frequency signal that is 60 dB or more below the noise floor. A lock-in amplifier may employ the digital signal processing equivalent to a nearly ideal superheterodyne and near ideal low-pass filter. This process can also be understood as homodyne direct down-conversion of an essentially-DC signal. The process extracts the amplitude and phase by:

(1) multiplying a received signal by a reference signal at the exact frequency of excitation. The waveform after multiplication will have a value of:

$$X = Average ( \frac{1}{2} {V}_{sig} {V}_{ref} cos ( {Θ}_{sig} - {Θ}_{ref} ) )$$

Where: V_{sig} is the receive signal,
V_{ref} is the reference signal,
Θ_{sig} is the phase of the receive signal, and
Θ_{ref} is the phase of the reference signal.

This value is a DC signal that is proportional to the signal amplitude time the phase offset measured at 0°. The DC value is obtained by averaging X over the entire dataset.

(2) Multiplying the received signal by a reference signal shifted by 90° at the exact frequency of excitation, i.e., in quadrature. All frequency components of the signal are cancelled out except for the frequency of interest. This value is a DC signal that is proportional to the signal amplitude times the phase offset measured at 90°. The amplitude and phase of the received signal can be calculated as:

$$\vert {V}_{s i g} \vert = \sqrt{{X}^{2} + {Y}^{2}}$$

$${Θ}_{s i g} = {tan}^{- 1} \frac{Y}{X}$$

$$and Y = {V}_{sig} sin Θ$$

All other frequency components that are not associated with the injected signal at resonance are attenuated to zero or approximately zero. A lock-in amplifier may be embodied in analog or the digital electronics or some combination of the two and that digital embodiments typically have significantly higher noise rejection, nominally 100 dB for digital versus 60 dB for analog. In some embodiments, a lock-in amplifier or phase-sensitive detector may be used to improve the noise rejection or SNR of measurements and, in some embodiments, such lock-in amplifier or phase-sensitive detector may be implemented in software, DSP, programmable logic, analog hardware, or some combination thereof.

Some embodiments of multi-port configurations or other configurations comprising multiple instruments may further comprise synchronization connections between instruments that may be used for phase-and frequency-synchronization of clocks or frequency references and, in some embodiments, such synchronization connections may comprise fiber optic or copper digital network connections, single-ended or differential analog or digital signals, pulse-per-second, wireless/radio links, or other suitable technique for clock or reference signal synchronization. In some embodiments, instruments may be connected to a data network, e.g., via Ethernet, to facilitate other capabilities and, in such embodiments, instruments' data network connections may be used as synchronization connections in addition to or instead of separate synchronization connections.

The features of the described embodiments may detect faults in a variety of different applications. The features described herein may be implemented in refrigeration systems or other cold-chain components to, for example, reduce or mitigate food spoilage, damage to medication, or in matters involving temperature-sensitive hazardous materials. In some embodiments, the instrument 200 may be configured for use in healthcare or medical applications to improve the high-availability of life-critical or other domain-specific electrical systems. These systems may refer to those in use in the domain-or industry-specific or specialized electrical systems of public infrastructure, public utilities, public safety, industrial facilities, or military applications. In some embodiments, an instrument 200 may be configured to monitor the conductors of telecommunications or networking systems. Some embodiments may be configured for use in the oil and gas industry, or oil or gas rigs. Some embodiments of conductor fault detection instrumentation may be configured for use in aviation, aerospace, shipping and marine applications, railroads, or other transportation, conveyance, or shipping infrastructure, vehicles, or facilities.

The instrument 200 may be configured to detect faults comprising physical or mechanical damage to switching components, such as silicon-controlled rectifiers (SCRs), thyristors, MOSFETS, or IGBTs. The instrument 200 may also detect faults in components with inductive elements, such as motor windings or transformer windings. The instrument 200 may also detect the insulation or dielectric characteristics of conductors prior to damage.

The conductor fault detection instrumentation and techniques described herein may be implemented in healthcare or medical applications to improve the availability of life-critical or other electrical systems, such as those in use in public infrastructure, public utilities, public safety, industrial facilities, or military applications. As another example, the fault detection techniques described herein may be used to detect faults in components in telecommunications systems, oil/gas systems, aviation systems, aerospace systems, shipping and marine applications, railroads or other transportation systems, shipping infrastructure, vehicles, or the like.

The fault detection instruments or techniques described herein may be implemented to achieve temporary coupling to circuits for periodic or ad hoc conductor surveillance. Conductor surveillance instruments may further comprise adapters or connector systems whereby the channels of the instrument can be directly connected or coupled to a wiring harness, connector, or equivalent. In these configurations, instrument(s) may be configured automatically or by the user to analyze the specific circuits accessible via the respective connector or equivalent, or designated instruments may be configured for use with specific groups of circuits or with specific electrical system interfaces.

Conductor surveillance instruments may be connected or coupled to opposite ends of a cable harness or to multiple connection points along a cable harness and may be operated in the multi-port configuration described previously. This configuration may provide a better or more accurate assessment of the overall condition of the respective conductors. In some embodiments, fault detection instruments may be configured to detect or localize high-resistance or faulty series connectors in a cable harness or bundle, for example, when a given cable harness may use connectors to pass through bulkheads or other structural elements.

In some applications, measurements of an energized circuit's voltage and current can be used to identify faults in attached equipment, such as for prognostics and diagnostics. For example, as the bearings of an electric motor wear or degrade over time, certain high-frequency content begins appearing in the motor's current and voltage waveforms. This content can indicate that a bearing needs to be serviced or replaced prior to the failure of the bearing, unscheduled downtime, possible damage to the motor, etc., and enables the motor to be serviced during a planned maintenance period. Evolving faults in switch-mode power supplies, such as failing capacitors, can be surmised from their current and voltage waveforms—and as new or changing high-frequency content, as non-compliant switching noise, or changes in power factor.

In some embodiments, predictive and condition-based maintenance of conductors and circuits comprises analysis of in-service current and voltage waveforms over time and conductor fault detection conducted from time-to-time on deenergized circuit. The data of such analysis is sourced from a fault detection instrument, possibly fitted with additional current and voltage measurement channels, and possibly in conjunction with a high-sample-rate, high-dynamic-range voltage and current measurement instrument.

A surveillance instrument may be configured as a handheld or otherwise portable instrument. In some embodiments, a handheld instrument may comprise a display and user input components, such as keys, a screen, a touchscreen, mouse, etc., collectively a “user interface.” The user interface may enable the user to view or change an instrument's configuration; initiate, terminate, or monitor scans or analyses of circuits; view present or historical data including analytical results; display the location of a fault; perform self-diagnostics or calibration, or otherwise control or manage other functions of the instrument. In some embodiments, a handheld instrument may be configured to be battery-powered and may further comprise built-in battery charging circuitry.

The instrument may be configured to display a fault's location, such as with reference to the physical topology of the electrical system. The instrument may represent the physical topology as a map or plan view of the electrical system under analysis and the system in which it is disposed.

A user may have the option to select or indicate the location(s) being probed by the instrument. For example, the user may select the location(s) from a list or with reference to the physical topology of the electrical system, such as via a map or plan view thereof.

A handheld instrument may have a small number of ports compared to permanently-installed instruments. Accordingly, a handheld instrument may only be able to probe the circuit under test at a few points.

Large or complex circuits may require a larger number of measurements/measurement points or locations to obtain accurate fault identification, characterization, or localization. In some embodiments, an instrument may provide recommendations regarding additional measurement points or locations to improve accuracy. These recommendations may be based on or otherwise incorporate data regarding the physical topology of the circuit being examined.

A handheld instrument may be configured (such as by a user) to perform measurements over a specific range of frequencies, i.e., a subset of the range the instrument is capable of generating or measuring. The frequency range selection(s) may be based at least in part on knowledge of the physical topology of the circuit, prior measurements of the circuit, user input, or some combination thereof. In some embodiments, the instrument may be configured to automatically expand the measured frequency range according to its measurements over the previously-selected frequency range, such as in response to a resonance not being detected in the previously-selected frequency range. In some embodiments, reducing the frequency range of a measurement may make measurements or tests faster, improve accuracy, (e.g., by avoiding measurements that could be misleading to the algorithm(s)), reduce data size or transfer requirements, conserve power of an instrument (whether handheld or remote), or improve battery life.

An instrument's physical location may be determined, in whole or in part, using one or more wireless localization technologies such as GPS, cellular/mobile network localization, or Wi-Fi network localization. In some embodiments, an instrument's physical location, including its points-of-coupling to the electrical system under test, may be determined at least in part using computer vision, machine vision, object recognition, self-tracking, optical tracking, or other relevant technologies or methods.

An instrument, including a handheld instrument, may be configured to communicate via a wired; optical; or wireless connection or network such as Ethernet, USB, Bluetooth®, Wi-Fi, mobile or cellular networks, LTE, 5G, satellite, CAN, Modbus, or serial. A handheld instrument may be configured to communicate with a control server or other external system such as the remote system 102 of FIG. 1. In embodiments that include a handheld instrument, at least some calculations associated with fault detection, characterization, or localization may be performed by an external system in operative communication with the instrument. Similarly, a handheld instrument may store measurements, analytical results, or other data locally. In these embodiments, the stored data may later be transferred to an external system for archival or analytical purposes.

Some embodiments may incorporate galvanically-isolated wired data connections, such as galvanically-isolated USB interfaces, AC-coupled interfaces such as Ethernet, or optical media such as fiber optic or infrared. In some embodiments, at least one of an instrument's channels may be exposed via one or more modular or standardized connectors, such as banana plugs/jacks or coaxial connectors. In some embodiments, one or more of an instrument's channels may be disposed on or in a module which may be removeable and interchangeable with other modules. In some embodiments, modules of different types may have different capabilities, specifications, connectors, or other features. These various module types may be available to support several frequency ranges. For example, a first type may support frequencies from 0 Hz to 10 MHz and a second type may support frequencies from 10 MHz to 100 MHz. Some embodiments may be configured such that damage to a module, such as from exposure to excessive voltage or environmental damage, is isolated from the rest of the instrument, and therefore enabling a damaged module to be replaced with a spare.

Components described herein such as a handheld instrument may be configured to be resistant to environmental contamination. The handheld instruments described herein may be resistant to contamination such as the ingress of particles or liquids; resistant to solvents or harsh chemicals; resistant to damage due to vibration, impact, or high accelerations; or configured to maintain operability in extreme cold or extreme heat. The handheld instruments may be configured to comply with regulatory or safety standards applicable to electronic instruments, such as NFPA 70E CAT ratings or IEC 60529 ingress protection (IP) ratings. In some embodiments, CAT ratings may be effectuated, in part, by incorporating high-voltage electromechanical relays and attendant protection circuitry of channel inputs.

Some embodiments of instruments may be configured to be intrinsically safe (e.g., per EN 60079-11:2023) or otherwise safe for use in hazardous or explosive atmospheres. The use of low-energy, low-voltage signals for fault detection, characterization, and localization taught herein may make some embodiments inherently safer (generally and with regard to intrinsic safety) than alternative methods, such as those reliant on high-voltage insulation/resistance testers or “thumpers”, both of which types may rely on the generation of sparks/arcs.

In some embodiments, a handheld instrument may comprise other electrical/electronics instrumentation or measurement functions, such as those of a multimeter, oscilloscope, vector network analyzer, current meter, voltmeter, or other portable instrument. In some embodiments, such functions may share components, such as ADCs or DACs, or channels with fault-detection functions. One or more channels or functions of an instrument may be enabled by installing a software or hardware license key or equivalent.

Aspects of the measurement and instrumentation methods taught herein may be affected by ambient conditions, such as temperature or humidity, which may affect the accuracy or precision of the measurements themselves or of fault identification, characterization, or localization. Some embodiments may comprise methods for compensating for ambient conditions and mitigating said effects (“compensation” for “ambient conditions”). The ambient compensation methods taught herein may be useful or applicable in other measurement or instrumentation methods, apparatuses, or applications, including those that may or may not relate to conductor fault analysis.

Some embodiments may comprise a method for compensating for ambient conditions comprising the following steps:

(a) Measuring ambient conditions that may affect relevant measurements, such as temperature, humidity, vibration, flexion or bending. In some embodiments, such measurements of ambient conditions may be made by the instrument 200 or instrumentation system itself and/or using other measurement instruments or equipment. In some embodiments, such measurements of ambient conditions may be collected periodically or sporadically over one or more time or measurement intervals. These intervals may relate to or be based on specific operating conditions, environments, or geographical locations. Ambient conditions may be measured in multiple locations, such as at or in an instrument 200 or at specific or representative locations in or proximate to the instrumented circuit(s) or system(s).

(b) Modelling the effects of ambient conditions on the instrument 200 and/or the instrumented circuit(s) and characteristics of the same. For example, the values of resistors or other passive components and characteristics of semiconductor devices typically vary in proportion to temperature. This variation may lead to errors or uncertainties in measurements or calculations. For example, humidity may affect contact resistance, such as at probing points or between a monitored conductor and a reference conductor. Conductor length varies with temperature, which, particularly for long conductors, may affect localization accuracy. Flexing or bending of conductors may change their impedance characteristics. Vibration may couple into certain components of an instrument 200, such as ceramic capacitors, producing so-called microphonic effects, which may introduce noise or frequency content. In some embodiments, such modelling may be incorporated, implicitly or explicitly, into fault identification, characterization, or localization algorithms per se or via training of the same.

(c) Measuring ambient conditions during an instrument's 200 operation (“real-time ambient conditions”). Real-time ambient conditions may be measured by an instrument 200 configured with appropriate sensors or by an external system that communicates measurements of real-time ambient conditions to an instrument 200 or a control server.

(d) Using the model(s) of step (b) or outputs of the same and the measurements of real-time ambient conditions of step (c), (i) calibrate or apply adjustments to an instrument's raw measurements to compensate for the effects of ambient conditions and/or (ii) as inputs to fault identification, characterization, or localization algorithms. In some embodiments, the models or algorithms of steps (b) or (d) (ii), above, may be, without limitation, physics-based, simulation-based, machine-learning-based, or artificial-intelligence-based, or combinations thereof. In some embodiments, the methods of calibrating or applying adjustments of step (d) (i), above, may employ, without limitation, Kalman or Extended Kalman filters, optimization algorithms, statistical methods, or machine learning or artificial intelligence techniques or models. In some embodiments, an operator may provide additional input to the ambient condition compensation methods taught above to improve accuracy or performance.

The methods, systems, and devices discussed above are examples. Various configurations may omit, substitute, or add various procedures or components as appropriate. For instance, in alternative configurations, the methods may be performed in an order different from that described, and that various steps may be added, omitted, or combined. Also, features described with respect to certain configurations may be combined in various other configurations. Different aspects and elements of the configurations may be combined in a similar manner. Also, technology evolves and, thus, many of the elements are examples and do not limit the scope of the disclosure or claims.

Embodiments of the present disclosure, for example, are described above with reference to block diagrams and/or operational illustrations of methods according to embodiments of the present disclosure. The functions/acts noted in the blocks may occur out of the order as shown in any flowchart. For example, two blocks shown in succession may in fact be executed substantially concurrent or the blocks may sometimes be executed in the reverse order, depending upon the functionality/acts involved. Additionally, or alternatively, not all of the blocks shown in any flowchart need to be performed and/or executed. For example, if a given flowchart has five blocks containing functions/acts, it may be the case that only three of the five blocks are performed and/or executed. In this example, any of the three of the five blocks may be performed and/or executed.

A statement that a value exceeds (or is more than) a first threshold value is equivalent to a statement that the value meets or exceeds a second threshold value that is slightly greater than the first threshold value, e.g., the second threshold value being one value higher than the first threshold value in the resolution of a relevant system. A statement that a value is less than (or is within) a first threshold value is equivalent to a statement that the value is less than or equal to a second threshold value that is slightly lower than the first threshold value, e.g., the second threshold value being one value lower than the first threshold value in the resolution of the relevant system.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations only, and does not limit the scope, applicability, or configurations of the claims. Rather, the preceding description of the configurations will provide those skilled in the art with an enabling description for implementing described techniques. Various changes may be made in the function and arrangement of elements without departing from the spirit or scope of the disclosure.

Having described several example configurations, various modifications, alternative constructions, and equivalents may be used without departing from the spirit of the disclosure. For example, the above elements may be components of a larger system, wherein other rules may take precedence over or otherwise modify the application of various implementations or techniques of the present disclosure. Also, a number of steps may be undertaken before, during, or after the above elements are considered.

Having been provided with the description and illustration of the present application, one skilled in the art may envision variations, modifications, and alternate embodiments falling within the general inventive concept discussed in this application that do not depart from the scope of the following claims.

What is claimed is:

1. A first instrument comprising:
at least one signal generator;
at least one resistor;
at least one voltage measurement device including a positive input and a negative input;
at least one monitored conductor terminal coupled to a monitored conductor;
at least one reference conductor terminal coupled to a reference conductor; and
at least one processor operably connected to the at least one signal generator and the at least one voltage measurement device,
wherein:
an output of the at least one signal generator is electrically coupled to the at least one monitored conductor terminal via the at least one resistor,
the positive input of the voltage measurement device is electrically coupled to the at least one resistor,
the negative input of the voltage measurement device is electrically coupled to the at least one reference conductor terminal; and
the at least one processor is configured to:
instruct the at least one signal generator to output a sinusoid waveform of at least a first frequency,
read the at least one voltage measurement device,
calculate the resonant frequency or the impedance of the circuit coupled to the at least one monitored conductor terminal and at least one reference conductor terminal, and
calculate and output at least one of the resonant frequency or the impedance of the circuit at the resonant frequency.

2. The instrument of claim 1 further comprising a prescribed set of two or more frequencies wherein, for each frequency F in the set, the at least one processor configures the at least one signal generator to:
output a sinusoid of frequency F,
read the at least one voltage measurement device, and
record the voltage at frequency F.

3. The instrument of claim 2 wherein the at least one processor is further configured to calculate the at least one resonant frequency of the circuit coupled to the at least one monitored conductor terminal and the at least one reference conductor terminal from the set of measured voltages and calculate and output the impedance of the circuit at each frequency.

4. The instrument of claim 3 wherein the at least one processor is further configured to input the set of frequencies and measured voltages into at least a first algorithm that determines and outputs at least one of whether a fault exists, impedance of a fault, or the location of a fault.

5. The instrument of claim 4 wherein the input to the at least first algorithm further comprises data about at least one of the topology, physical characteristics, or electrical characteristics of the electrical network coupled to the at least one monitored conductor.

6. The instrument of claim 4 wherein the input to the at least first algorithm comprise at least a first set of frequencies and measured voltages recorded at a first time and a second set of frequencies and measured voltages recorded at a second time.

7. The instrument of claim 4 wherein the first algorithm comprises a machine learning algorithm or artificial intelligence algorithm.

8. The instrument of claim 1 wherein the at least one processor is further configured to use the at least one voltage measurement device together with the at least one signal generator as a phase-sensitive detector or as a lock-in amplifier.

9. The instrument of claim 1 further comprising a second voltage measurement device electrically coupled to the monitored conductor at a location different from that of the monitored conductor terminal.

10. The instrument of claim 1 wherein the instrument further comprises at least one network interface operably connected to at least one processor.

11. The instrument of claim 1 wherein the instrument is configured to communicate with at least one of a second instrument or another network node via at least one network.

12. The instrument of claim 11 wherein the first instrument and second instrument are configured to coordinate via the at least one network to establish or maintain a phase relationship between the signal generator of the first instrument and the reading of the voltage measurement device of the second instrument.

13. The instrument of claim 11 wherein:
the signal generator is coupled to the first monitored conductor and the first reference conductor,
a voltage measurement device of the second instrument is electrically coupled to the first monitored conductor and the first reference conductor, and
the first instrument and the second instrument are configured to coordinate via the at least one network.

14. The instrument of claim 13 wherein the first instrument is configured to output a sinusoid of at least a first frequency and the second instrument is configured to read a voltage via a second voltage measurement device and record the voltage at the at least first frequency.

15. The instrument of claim 1 wherein the instrument is configured to transmit at least one frequency and measured voltage to another network node via at least one network.

16. The system of claim 15 wherein the network node is configured to receive frequencies and measured voltages from the instrument, input the frequencies and measured voltage into at least a first algorithm that determines and outputs at least one of whether a fault exists or the location of a fault.

17. The instrument of claim 1 wherein at least one of the monitored conductor or the reference conductor is a conductor of a cable harness, wiring harness, network cable, coaxial cable, twinaxial cable, triaxial cable, power transmission line or network, circuit board, backplane, differential pair, grounding network, hull, chassis, or structure, undersea or underground cable, multiconductor cable, antenna or antenna system, semiconductor device, electric motor, or transformer.

18. The instrument of claim 7 wherein the first algorithm is configured to use transfer learning.

19. The instrument of claim 1 wherein the instrument is configured such that the positive input of the first voltage measurement device is electrically coupled to a first terminal of the at least one resistor and a second terminal of the at least one resistor is electrically coupled to the monitored conductor, and a positive input of a second voltage measurement device is electrically coupled directly to the monitored conductor.

20. The instrument of claim 19 wherein the instrument is configured to read a value from the first voltage measurement device and a value from the second voltage measurement device concurrently, and to calculate the current through the at least one resistor based on knowledge of the resistor.
